(19) United States
(12) Patent Application Publication
(10) Pub. No.: US 2026/0098906 A1
(43) Pub. Date: Apr. 9, 2026

(54) SYSTEM AND METHOD FOR IN-OPERANDO HEALTH MONITORING FOR LITHIUM-ION BATTERIES IN ELECTRIC PROPULSION USING DEEP LEARNING

(71) Applicant: Purdue Research Foundation, West Lafayette, IN (US)

(72) Inventors: Vikas Tomar, West Lafayette, IN (US); Meghana Sudarshan, West Lafayette, IN (US); Alexey Yourievich Serov, Indianapolis, IN (US); Jaya Vikeswara Rao Vajja, West Lafayette, IN (US)

(73) Assignee: Purdue Research Foundation, West Lafayette, IN (US)

(21) Appl. No.: 19/348,739

(22) Filed: Oct. 2, 2025

Related U.S. Application Data
(60) Provisional application No. 63/703,580, filed on Oct. 4, 2024.
(60) Provisional application No. 63/703,594, filed on Oct. 4, 2024.

(51) Int. Cl. G01R 31/367; G01R 31/374; G01R 31/3842; G01R 31/392; G01R 31/396; G06N 3/09; H01M 10/42; H01M 10/48

(52) U.S. Cl. CPC G01R 31/367; G01R 31/374; G01R 31/3842; G01R 31/392; G01R 31/396; G06N 3/09; H01M 10/425; H01M 10/486; H01M 2010/4271

(57) ABSTRACT

A method of predicting battery end of life based on a small dataset of sensor data include training a deep learning network using a plurality of a priori generated training datasets, receiving sensor data from a plurality of sensors in real-time coupled to one or more cells in a battery pack as the one or more cells are used in a present discharge cycle to thereby generate a plurality of new unseen sensor datapoints, and applying the new unseen sensor datapoints to the trained deep learning network to thereby generate operational recommendations to achieve one or both of i) extend end of life of the battery pack, and ii) extend operational time of the battery pack during the present discharge cycle or a future discharge cycle.

### CROSS-REFERENCE TO RELATED APPLICATIONS

The present non-provisional patent application is related to and claims the priority benefit of U.S. Provisional Patent Application Ser. 63/703,594, filed Oct. 4, 2024, and also claims the priority benefit of U.S. Provisional Patent Application Ser. 63/703,580, filed Oct. 4, 2024, the contents of each of which are hereby incorporated by reference in its entirety into the present disclosure.

### STATEMENT REGARDING GOVERNMENT FUNDING

This invention was made with government support under N00014-22-1-2079 awarded by the Office of Naval Research. The government has certain rights in the invention.

### TECHNICAL FIELD

The present disclosure generally relates to a system and method for testing batteries, and in particular using a battery management system (BMS) and a small dataset for predicting end of life (EOL) of Lithium-ion based batteries (LIBs) as well as in-operation management.

### BACKGROUND

This section introduces aspects that may help facilitate a better understanding of the disclosure. Accordingly, these statements are to be read in this light and are not to be understood as admissions about what is or is not prior art.

Technologies running on LIB are nowadays widespread. In fact, the importance of LIBs and associated technology cannot be overstated in the current technological landscape. Diverse systems, ranging from electric vehicles and aerial drones to portable electronic devices, rely extensively on the unhazardous operation of LIB technology such as avoiding fire, thermal runaway, etc. An LIB offers high energy density, long cycle life, fast charging, low self-discharge rate, wide operating temperature range, versatility in design, reduced maintenance, and environmental friendliness compared to conventional rechargeable battery technologies such as nickel-metal hydride (NiMH), and nickel-cadmium (NiCd) batteries, etc. The aging of an LIB decreases its capability to store energy and provide power to the application. So, state of health (SOH) is an important parameter to know the battery aging. Many challenges are faced for accurate estimation of SOH due to internal battery chemistry and the difficulty in measuring the individual parameters such as voltage, current, temperature, capacity, and so on. This underscores the paramount importance of precise sensing and monitoring mechanisms to safeguard their durability and dependability. A BMS plays a key role in accurately sensing and monitoring battery parameters ensuring the battery operates safely for longevity and reliability.

The design of a BMS is historically application-specific, closely tied to the specific battery or cells employed, the power demands from the system, and the level of complexity desired. Alongside the SOH of the battery, state of charge (SOC), and remaining useful life (RUL) are common indicators of battery health. Often, these indicators are derived from proprietary data acquisition (DAQ) setups employed for data collection, which can restrict flexibility and introduce logistical complexities regarding connectivity. DAQ configurations for LIBs can provide essential data such as voltage, current, and temperature for deep learning applications but often suffer from being bulky, expensive, and tailored to specific research batteries or battery packs. Frequently, there is an insufficient description of the cost involved in data collection. BMS, however, collects the required data for calculating the battery performance parameters. It provides flexibility in collecting a wide range of data for different applications. Integrating deep learning techniques with advanced BMS presents a promising approach for early prediction of battery performance, overcoming challenges associated with data collection methods, and offering scalability for diverse applications.

Along with the SOH of the battery, SOC, RUL, and the C rate are also important parameters for the performance of LIB. C rate is the ratio of battery current to the rated capacity. An increase in the C rate of the battery causes a capacity fade or increase in battery degradation and a reduction in time to complete one full charge or discharge cycle. These increases in the C rate are often required for applications like aviation, electric vehicle charging, etc. Previously researchers performed testing on overcharge and over-discharge rates to investigate the fire and thermal characteristics of batteries. They observed that the surface temperature of the battery increased with an increase in the C rate. Previous work on high C rates has also involved the development of accelerated models for the degradation of batteries. In the battery deep learning domain, data holds paramount importance. However, current data collection methods often face challenges such as complex setups and sensor accuracy ambiguities. A necessity emerges to develop an innovative, portable BMS framework for collecting voltage, current, and temperature data in a versatile range of applications like high C rates, encompassing both stationary battery loads and dynamic, mobile systems. A combined and streamlined in-operando system such as BMS with deep learning offers benefits over previous work done in this space. It seamlessly integrates with modern cloud BMS designs. Seamless integration with modem cloud BMS designs is crucial because it ensures efficient and effective utilization of resources while providing scalability and flexibility to adapt to evolving technological needs.

Therefore, there is an unmet need for a novel system and a method for predicting EOL that is capable of interfacing with a variety of different sensors designed to provide real-time conditions of a battery.

### SUMMARY

A method of predicting battery end of life based on a small dataset of sensor data is disclosed. The method includes training a deep learning network using a plurality of apriori generated training datasets, receiving sensor data from a plurality of sensors in real-time coupled to one or more cells in a battery pack as the one or more cells are used in a present discharge cycle to thereby generate a plurality of new unseen sensor datapoints, and applying the new unseen sensor datapoints to the trained deep learning network to thereby generate operational recommendations to achieve one or both of i) extend end of life of the battery pack, and ii) extend operational time of the battery pack during the present discharge cycle or a future discharge cycle.

A system for predicting battery end of life based on a small dataset of sensor data is also disclosed. The system includes a plurality of sensors coupled to one or more cells in a battery pack and adapted to provide real-time sensor data. The system also includes a battery management system configured to operate the one or more cells. Furthermore, the system includes a processing system including a processor executing instruction residing on a non-transitory memory, the processor configured to receive the real-time sensor data. The processor is configured to communicate with a deep learning network, wherein the deep learning network is trained based on a plurality of apriori generated training datasets. The processor is configured to receive the real-time sensor data as the one or more cells are used in a present discharge cycle to thereby generate a plurality of new unseen sensor datapoints, and apply the new unseen sensor datapoints to the trained deep learning network to thereby generate operational recommendations to achieve one or both of i) extend end of life of the battery pack, and ii) extend operational time of the battery pack during the present discharge cycle or a future discharge cycle.

### BRIEF DESCRIPTION OF DRAWINGS

FIGS. 1a and 1b which are plots of capacity in ampere-hour (Ah) vs. cycle number for three different cathode cell chemistries (Nickel Manganese Cobalt Oxide (NMC) and Nickel Cobalt Aluminum Oxide (NCA) in FIG. 1a; and Lithium Iron Phosphate (LFP) in FIG. 1b) from an experimental study conducted by Sandia National Lab.

FIG. 2 is a block diagram of a system according to the present disclosure having several components shown therein.

FIG. 3 is an example block diagram showing exchange of information in a deep learning network first during the training phase where the network is trained with a priori information including capacity vs. cycle, along with data from a sensor suite including ambient temperature, pack voltage, and cell temperature, and then during testing phase, when the network is provided previously unseen data, again data from a sensor suite including ambient temperature, pack voltage, and cell temperature, used by the network to provide a prediction as well as optionally monitor safety concerns and optimize battery operation to extend range and life of battery.

FIG. 4 is a detailed schematic of the battery management system (BMS) sensor network, illustrating the integration of current, voltage, and temperature sensors with a microcontroller and communication module for real-time monitoring and data transmission.

FIG. 5 is a schematic of a drone with a BMS on top, which stores the voltage, temperature, and current and where current was used to calculate the SOC of the battery which helps to predict the discharge capacity by using a CD-Net.

FIGS. 6a, 6b, 6c, and 6d are schematic overview of an experimental setup: where FIG. 6a provides a top view of BMS with all the sensors used in these experiments, FIG. 6b is a schematic representation of BMS and quadcopter connectivity with batteries, FIG. 6c is a schematic showing in operation experimental setup of quadcopter along with batteries and BMS, and FIG. 6d is a schematic of an 18650 NCA batteries used in batteries where RTD is placed in the middle of the surface.

FIG. 7 is a graph of voltage in volts and deviation of voltage in volts both vs. time in hours, showing comparison of voltage readings collected from both BMS and BAn on top with the deviation between them plotted on the bottom indicating the error between BMS and BAn readings is minimal.

FIG. 8a is a graph of current in amperes vs. time in hours showing current collected from both BMS and BAn.

FIG. 8b is a graph of deviation in current in amperes vs. time in hours showing good match for current collected from both BMS and BAn except during the transition from charge to discharge or discharge to charge for on-ground experiments.

FIG. 9a is a graph of temperature in ° C. vs. time in hours showing surface temperature for a 4-cell battery pack including the ambient temperature (T5=TA) data logged by BMS for 10 cycles performed on ground.

FIG. 9b is another graph of temperature in ° C. vs. time in hours showing first complete cycle performed on ground, peaks observed at the end of constant current for both charge and discharge.

FIG. 10a is a graph of current in ampere vs. time in hours for current and voltage collected by BMS performing random flying pattern of the drone, current and voltage were collected over 10 cycles performed on drone with required discharge current from the battery pack to fly the drone.

FIG. 10b is another graph of current in ampere vs. time in hours similar to FIG. 10a, but where current discharging at higher ° C. rates in real-time while voltage dropping from 16.8V to 10V for one discharge cycle while flying the graph was for 5^{th} cycle out of 10, note that discharge cycle is less than an hour.

FIG. 11a is a graph of temperature in ° C. vs. time in hours showing surface temperature collected by BMS performing random flying pattern on drone including TA as ambient temperature using a 4 cell Lithium-ion based battery (LIB) pack where similar pattern was observed for the 10 cycles performed on drone with TA dipping during the flight.

FIG. 11b is similar to FIG. 11a but provides data for one discharge cycle while flying in which a temperature growth was observed over time, note that discharge cycle is less than an hour.

FIGS. 12a and 12b are graphs of capacity in Ah vs. cycle number showing capacity predictions made on the CD-Net model based on the data collected from BMS for both on-ground experiments (FIG. 12a) and while flying on a drone with capacity being unstable after 4 cycles (FIG. 12b).

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 15%, within 10%, within 5%, or within 1% of a stated value or of a stated limit of a range.

In the present disclosure, the term “substantially” can allow for a degree of variability in a value or range, for example, within 85%, within 90%, within 95%, or within 99% of a stated value or of a stated limit of a range.

A novel system and a method for predicting EOL that is capable of interfacing with a variety of different sensors designed provide real-time conditions of a battery. Towards this end, a comprehensive framework for a battery management system (BMS) capable of meeting electric propulsion-specific requirements of operating in-operando and integrating a deep learning-based capacity prediction algorithm, a capacity degradation network (CD-Net), are presented.

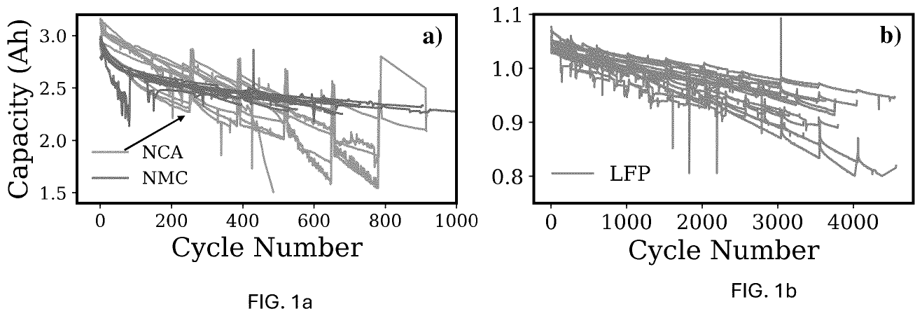

Capacity loss due to aging of Lithium-ion based batteries (LIBs) has been studied extensively as a combination of an initial quasi-linear stage and steep accelerated nonlinear trends. Examples of these multi-stage aging trends can be observed in FIGS. 1a and 1b which are plots of capacity in ampere-hour (Ah) vs. cycle number for three different cathode cell chemistries (Nickel Manganese Cobalt Oxide (NMC) and Nickel Cobalt Aluminum Oxide (NCA) in FIG. 1A; and Lithium Iron Phosphate (LFP) in FIG. 1B) from an experimental study conducted by Sandia National Lab. These figures show distinct multi-stage degradation trends with reference to cell chemistries, a phenomenon due to chemical reactions within LIBs known in the prior art. The data characterizes capacity fade in LIBs with three stages: 1) an acceleration stage due to sudden Lithium loss showing a steep dip, 2) a stabilization stage with solid-electrolyte interphase thickening and side reaction decay, and 3) a saturation stage with active material loss. Various causes for the switch between different capacity fade stages that have been proposed are based on multiple coupled degradation mechanisms and are specific to cathode cell-chemistries in LIBs. Specifically, researchers have described cell chemistry and operational conditions affecting the path towards EOL and exact degradation mechanisms of LIBs. Such trends with cell chemistry can also be identified in many other publicly available datasets from various organizations such as National Aeronautics and Space Administration Prognostics Center of Excellence (PCoE), National Renewable Energy Laboratory repository, Hawaii Natural Energy Institute, University of Maryland, and Oxford University to name a few.

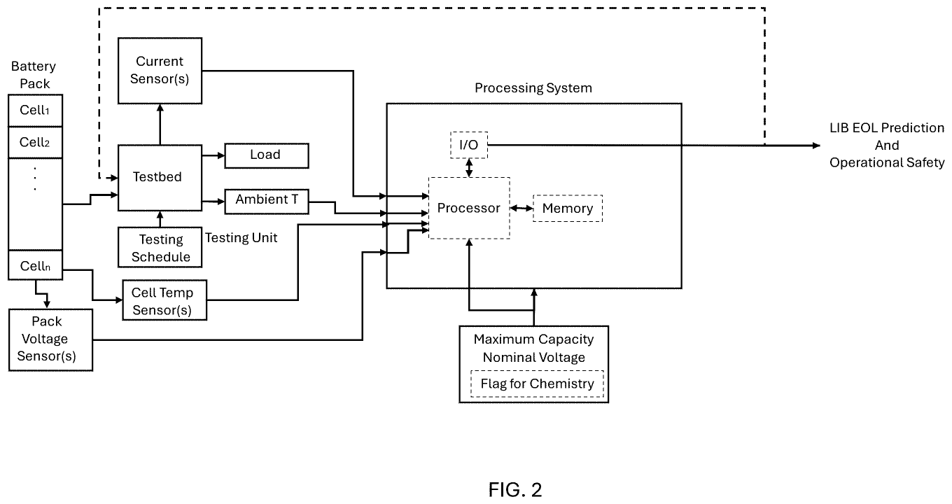

Reference is made to FIG. 2, which is a block diagram of a system according to the present disclosure having several components shown therein. FIG. 2 provides a battery pack comprised of a plurality of cells (Cell₁, Cell₂, . . . Cellₙ) coupled to a testbed for testing one or more of the plurality of cells. The testbed is coupled to a testing unit providing a testing schedule. The testbed is also coupled to a load intended to discharge the one or more cells of the plurality of cells. Additionally, a plurality of sensors, including one or more current sensors, e.g., a sense resistor, or an ammeter, is coupled to the testbed to measure current drawn out of the one or more cells of the plurality of cells. Additionally, the sensor suite includes an ambient temperature sensor, a pack voltage sensor which may include one or more voltage sensors providing voltage at the battery pack level or at each individual cell level, and one or more cell temperature sensors adapted to provide temperature of the one or more cells. The testbed is therefore responsible for cycling the one or more cells, that is charging and discharging in a cyclical manner. Output of the current sensor and all other sensor outputs are provided to a processing system having a processor, e.g., a micro-controller with one or more analog to digital converters, a micro-processor coupled to a standalone analog to digital converter (not shown), a digital signal processor, a field programmable gate array, etc. The sensor data including the current sensor data are each an analog signal that is converted to a digital signal and is time-stamped to generate a time-based digital records, e.g., current in ampere vs. time in seconds, which is then converted to capacity which is a measure of charge accumulation or discharge as a function of time (typically provided as ampere hour) vs. cycle. The processing system further may include a memory block (shown as an off-chip memory or can be an on-chip memory on the processor) having non-transitory memory for storing instructions are executed by the processor to carry out the method of the present disclosure. Additionally, the processing system may include an input-output (I/O) block in communication with the processor and capable of providing an output representing prediction of EOL by the system of the present disclosure. Additionally, the I/O block may optionally receive signals from the processor related to safety parameters that can be provided as real-time feedback to the testbed, thus stopping the testing procedures enabled by the testing unit when such parameters indicate safety issues. Additionally, the processing system receives various information about the battery pack such as maximum capacity, nominal voltage, and optionally a flag indicating the type of cathode chemistry for the battery under test.

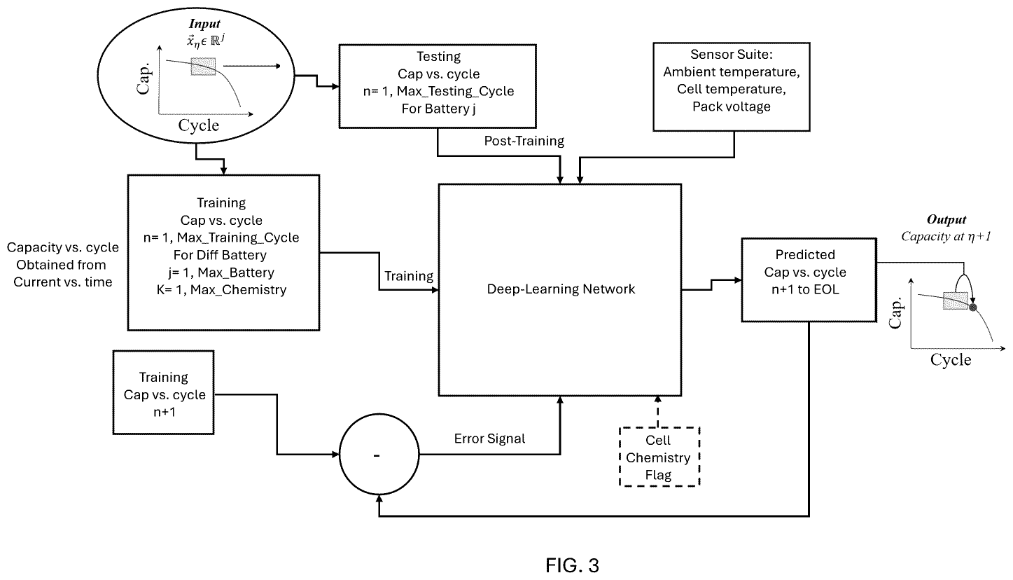

The processor and memory, according to the present disclosure provide a machine learning methodology often referred to as a deep learning network. Such a network uses interconnected nodes in a layered structure (e.g., an input layer, hidden layers, and an output layer) connected via a large number of connections with associated weights, as is known to a person having ordinary skill in the art. One example is a neural network. Referring to FIG. 3, an example block diagram is provided showing exchange of information in such a network first during the training phase where the network is trained with a priori information including capacity vs. cycle, along with data from a sensor suite including ambient temperature, pack voltage, and cell temperature, and then during testing phase, when the network is provided previously unseen data, again data from a sensor suite including ambient temperature, pack voltage, and cell temperature, used by the network to provide a prediction as well as optionally monitor safety concerns.

Referring to FIG. 3, large training data is provided to the deep learning network. For example, there may be 2000 cycles for a particular type of battery chemistry (e.g., Nickel Manganese Cobalt Oxide (NMC) and Nickel Cobalt Aluminum Oxide (NCA), see e.g., FIG. 1A, Lithium Iron Phosphate (LFP), see e.g., FIG. 1B to name a few such chemistries. As alluded to above, capacity vs. cycle may be provided in the form current vs. time, or simply capacity vs. cycle, however, the former is convertible to the latter. The deep learning network may receive the large capacity vs cycle training data in a chemistry-independent fashion, i.e., some training sets may be for one chemistry and other training set for other chemistry. Alternatively, the training dataset may be accompanied by a cell chemistry flag to train the network specifically for each type of chemistry. For example, if there are four different chemistries of interest, a 2-bit flag may be used to train the network with selective datasets for the associated chemistries. Regardless of whether chemistry-selective or chemistry-independent, the network is trained with a large dataset (e.g., 2000 cycles) for each type of chemistry, based on a large number of battery datasets for each type of chemistry (that is, for, e.g., LFP battery chemistry, 4000 cycles of capacity data is presented to the network (i.e., Max_Training_Cycle=4000), and 80 datasets of capacity vs. cycle from 80 different, e.g., LFP, batteries (i.e., Max_Battery=80) is presented, e.g., each having 4000 cycles). There may be 4 different types of battery chemistry (i.e., Max_Chemistry=4). Generally, the network generates future capacity vs. cycle predictions up to EOL (e.g., 80% capacity of maximum capacity). During the training, predicted values from the network are used as feedback against the a priori training data to generate an error signal that can be used to update the network, e.g., the weights. Once the training is complete, the network may be tested (not shown) with known additional capacity vs. cycle data to ensure network output is indeed in compliance with the additional capacity vs. cycle data based on predicted values. These additional datasets represent unseen data, however, this unseen data (not shown) still represents part of testing of the network.

When satisfied with the testing phase, the system and the method of the present disclosure provides unseen novel data that is provided in much smaller sizes. For example, capacity vs. cycle novel data may be for only, e.g., 80 LFP cycles, requiring a much shorter testing period (i.e., days vs. years). This dataset is shown in the Testing block providing post training datasets, including capacity vs. cycle for n=1 to Max_Testing_Cyle (e.g., 80) for a specific battery (shown as Battery j) with or without a battery chemistry flag, depending if the network is trained based on a chemistry-specific or chemistry-independent regime as discussed above.

It should be appreciated that while a major thrust of the present disclosure is directed to EOL prediction based on a plurality of sensor data chemistry-specific or chemistry-independent battery designs, another important aspect of the present disclosure is directed to managing operational parameters of the device in which the LIB batteries are installed in order to optimize battery life. For example, the deep learning network of the present disclosure may be trained and used in operation such that current ramp up from a first level, e.g., 0 Amps, to a steady state level or a second level when a load is connected to the LIB pack is retarded in order to avoid certain life-reducing events. Alternatively, charging cycle may be optimized based on, e.g., a predetermined schedule, or a user-defined, tradeoffs such that, e.g., battery life is maximized. Thus, the deep learning network may provide additional signals to the charging circuit, or to the battery management system of the LIB pack to achieve said optimization.

Different electric vehicle types may require different optimization for extending range of operation or alternatively extending life of battery. For example, for vehicles, such as electric vehicles (EVs), electric bicycles (e-bikes), and electric buses (e-buses), range forecasting may include real-time capacity prediction which allows accurate range estimation. However, for electric drones and unmanned aerial vehicles (UAVs), more importantly, predicting next-cycle capacity lets UAVs or their operators know if they can complete a flight safely, given that an in-flight out-of-battery will likely result in the destruction of these vehicles. For this class of vehicles (i.e., drones and UAVs), C-rate ((defined as the discharge or charge current)/battery capacity) optimization, may be based on forecasted capacity, allowing the user or a controller having a processor executing software on a non-transient memory automatically adjust power draw (propellers, payload) dynamically to extend flight time. Still further, in renewable energy and grid storage applications, end of life for a battery and ultimately a connected renewable energy system, such as a solar panel system or a wind mill system become crucial to avoid loss of service. In such systems, the system of the present disclosure can provide guidance as to which battery pack to use based on predicted health. Still yet, in consumer electronic applications such as cellular phones, a user or a controller having a processor executing software on a non-transient memory automatically adjust power draw to extend life of battery. Other applications, including industrial robots and heavy machinery, aerospace and defense, and medical devices can also be assisted from both end of life prediction as well as remaining charge in a charge/discharge cycle. In each of the above applications, predictions provided by the method of the present disclosure can be used to extend both end of life and operational time while the battery is being discharged by adjusting various parameters in operation based on neural network model and the sensor suite as feedback signals.

Accordingly, the BMS sensor suite of the present disclosure collects voltage, current, ambient temperature and temperature of each cell in a battery pack. These parameters are transferred wired or wirelessly (e.g., utilizing wifi) to a controller board or to a cloud server for real time monitoring by a user or by a controller having a processor executing software maintained on a non-transient memory for automatic manipulation of battery operational parameters. For example, ambient temperature or cell temperature plays a key role in battery operational degradation thus providing an opportunity in real time which helps a user or a controller to plan machine operation to extend operational time of the battery underload or extend the end of life of the battery. For example, based on a predefined threshold, temperature on each cell should not exceed 60 deg C. User can stop or limit the operation and restart in normal operating conditions, when the cells have cooled below the threshold, e.g., based on a hysteresis, or use a cooling system, accordingly. Using the machine learning model (CD-Net), predictions are provided to the user or a controller for the next cycle capacity and end of life of battery (, e.g., based on standard IEC 62660 80%) the user or the controller can make dynamic decisions to cut down power draw. Examples of parameters that the machine learning model uses to generate feedback signals used by the BMS to modify operation of the battery include but are not limited to: 1) ambient temperature, 2) temperature of each cell in a battery pack, 3) charge voltage, 4) maximum current input and maximum current drawn during charge and discharge cycle as well as current waveform, 5) cycle number (i.e., how many charge and discharge cycles has the battery experienced), 6) initial capacity of the battery when first placed in service, 7) depth of discharge (i.e., allowing the battery to discharge to a predetermined threshold, e.g., 20%), 8) real time C-rate, 9) next cycle capacity, and cell chemistry (i.e., using a flag that informs the model which cell chemistry is used during training and in operation). These parameters can be used to modify operation of the battery in order to achieve one or both of i) extend end of life, and ii) extend operational time of the battery during a current or future discharge cycle.

A circuit board was developed for the proposed BMS, focusing on collecting essential data for battery health prediction and initiating actions based on predictions. The developed BMS used the in-operando data for modern battery health prediction including battery voltage, current, and temperature. The collected data was then fed to a deep learning model for the live prediction of the battery health. The development process is described in brief in the following sections.

Accurate measurement of current and temperature was essential for the safe and efficient operation of electric propulsion systems. This section explores methodologies for current, voltage, and temperature measurement in battery applications. The enhancements were also highlighted to improve measurement accuracy and accommodate real-time scenarios. Through these efforts, we aim to ensure precise and reliable monitoring of critical parameters crucial for battery system performance and safety.

The current measurement was conducted using a shunt resistor inserted into the current path called a high-side current sensor. It measures the current in between the positive terminal of the power supply to the load. Current-voltage sensor INA219 was chosen due to its extensive monitoring capabilities, including the ability to handle variable pack voltages, extreme high and low voltages of the battery, up to 26 V, and a standard current measurement range of ±3.2 A. To accommodate real-time scenarios, where the current discharge from the battery exceeds ±3.2 A, the default 0.1Ω current shunt resistor was substituted with a 0.01Ω resistor. This adjustment enabled the system to accommodate a maximum current rating of ±32 A. The current-voltage sensor's maximum allowable voltage differential of 0.32 V drove the choice of the 0.01Ω resistor, corresponding to a maximum measurable current range of ±32 A when divided by the voltage differential according to equations (1), (2), (3) and (4). A Datasheet of INA 219 current and voltage sensor was used for programming this sensor to develop our BMS.

$${V}_{shunt} = {V}_{In}^{+} - {V}_{I \overline{n}} \qquad ( 1 )$$

$${V}_{{shunt}_{max}} = 0.32 V \qquad ( 2 )$$

$${R}_{shunt} = 0.01 Ω \qquad ( 3 )$$

$$Maximum Possible Current ( I ) = \frac{{V}_{s h u n t}}{{R}_{s h u n t}} = \pm 32 A \qquad ( 4 )$$

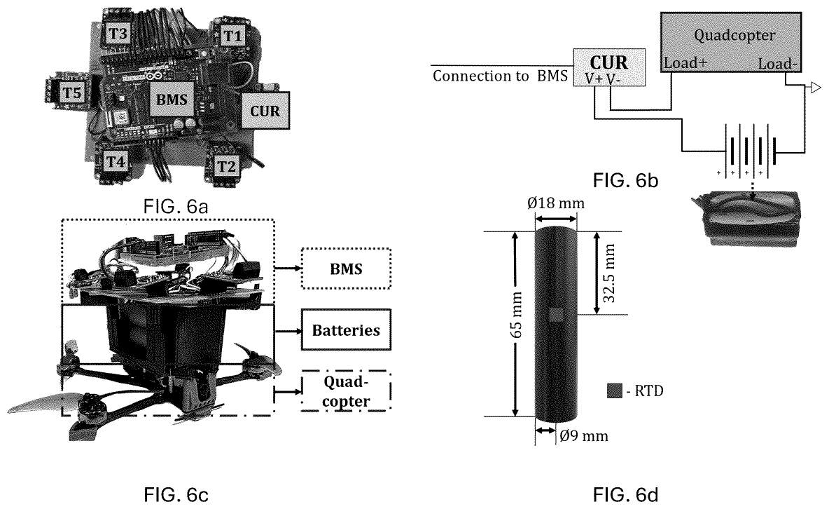

Temperature measurement for battery applications utilizes sensors that change resistance with temperature. Common sensor types include thermistors, thermocouples, and resistance temperature detectors (RTDs). RTDs, favored for their accuracy, are widely used to measure battery temperatures. In this study, the PT100 Adafruit MAX31865 sensor breakout boards were chosen due to their low power consumption (1.6 μW to 1.8 mW). The relation between the resistance of the temperature sensor and the temperature was obtained based on Callendar-Van Dusen's equation as shown in the equation (5):

$$R ( t ) = {R}_{0} ( 1 + α t + β {t}^{2} ) \qquad ( 5 )$$

where, R₀=100Ω (resistance at 0° C.) and α=3.90830*10⁻³. Five temperature sensor breakout boards were used, with one attached to each battery cell represented in FIG. 6a, discussed below, and an additional sensor on board for ambient temperature monitoring. This setup was calibrated by comparing the ambient temperature of the room to the ambient temperature collected by the sensor.

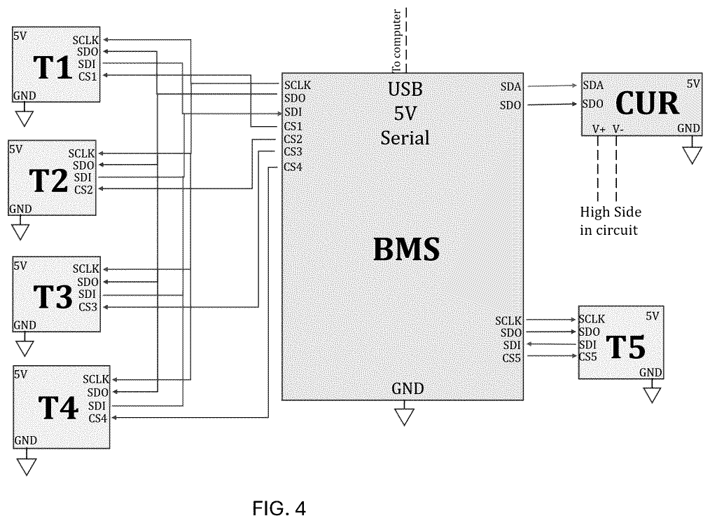

An Arduino Uno Rev 2 Wi-Fi circuit board, equipped with the ATmega4809 microcontroller, was chosen due to its data logging, pre-processing, and transmission capabilities. The device manages a network of sensors, including temperature sensors and current-voltage monitor sensors (obtained from Adafruit Industries). Its internal 5 V regulator, with a maximum current output of 0.8 A, was used to satisfy the input current and voltage requirements of the sensor network. Table 1 provides a detailed overview of the various connections made using an Arduino board with various sensors, as also depicted in FIG. 4, which is a detailed schematic of the BMS sensor network, illustrating the integration of current, voltage, and temperature sensors with a microcontroller and communication module for real-time monitoring and data transmission. This setup uses five different temperature sensors for collecting four cell surface temperatures and one ambient temperature. Serial clock (SCLK), serial data out (SDO), serial data in (SDI), and chip select (CS) were all signals utilized in the serial peripheral interface (SPI) protocol to connect the sensors to the microcontroller. Table 2 gives information on the required power for sensors and their usage in collecting parameters like voltage, current, and temperature.

TABLE 1
Description of the electrical terminals
on the sensor network wiring harness

| Type | Connection | Use |
|---|---|---|
| Power and Serial | USB | 5 V power supply as |
| | | well as serial |
| | | communication to the |
| | | main CPU |
| Ground | GND | Common star ground for |
| | | every component in the |
| | | sensor network |
| Shunt V+ | Current Sensor V+ | Positive Kelvin |
| | | connection from current |
| | | shunt to battery positive. |
| Shunt V− | Current Sensor V− | Negative Kelvin |
| | | connection from current |
| | | shunt to load positive. |

Arduino Pins

| | | |
|---|---|---|
| SCLK | Arduino Pin 13 | Clock line for SPI |
| SDO | Arduino Pin 12 | Serial Data Output for |
| | | SPI |
| SDI | Arduino Pin 11 | Serial Data Input for SPI |
| CS1 | Arduino Pin 10 | Chip Select Temperature |
| | | Sensor 1 |
| CS2 | Arduino Pin 9 | Chip Select Temperature |
| | | Sensor 2 |
| CS3 | Arduino Pin 8 | Chip Select Temperature |
| | | Sensor 3 |
| CS4 | Arduino Pin 7 | Chip Select Temperature |
| | | Sensor 4 |
| CS5 | Arduino Pin 6 | Chip Select Temperature |
| | | Sensor 5 |
| SCLK | Arduino Pin SCLK | Serial Data Clock for |
| | | I2C |
| SDO | Arduino Pin SDO | Serial Data Address for |
| | | I2C |

TABLE 2
Current and operating voltage requirements of the sensor network
used in the development of BMS in the present disclosure

| | | Operating | Maximum |
|---|---|---|---|
| Purpose | Sensors Used | Voltage | Supply Current |
| Pack voltage and | Adafruit INA219 | 3.0-5.5 V | 1 mA |
| current sensor | | | |
| Battery surface | Adafruit PT100 | 3.0-3.6 V | 3 mA |
| temperature | MAX31865 | | |
| sensors | | | |
| Ambient | Adafruit PT100 | 3.0-3.6 V | 3 mA |
| temperature | MAX31865 | | |
| sensor | | | |

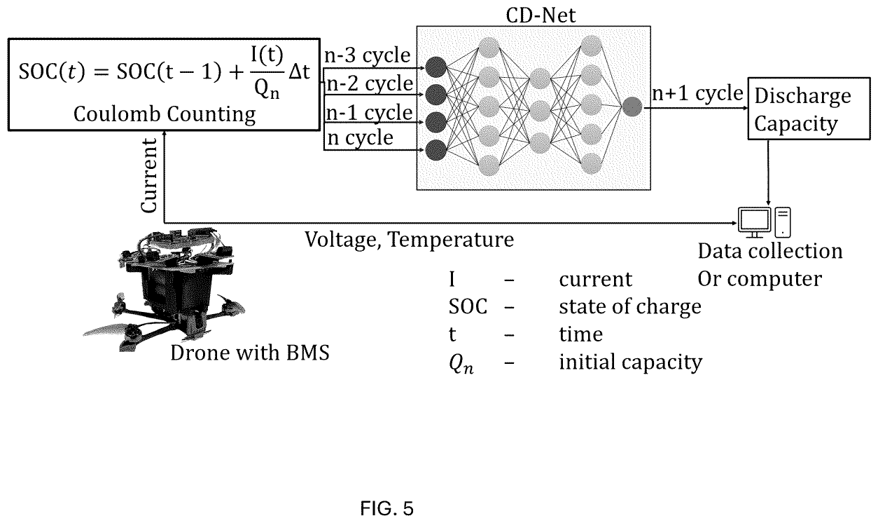

Voltage and temperature collected by the BMS were transferred to the computer or data collection facility. The current collected by the BMS was used to calculate the SOC of the battery by using the coulomb counting method as shown in FIG. 5, which is a schematic of a drone with a BMS on top, which stores the voltage, temperature, and current and where current was used to calculate the SOC of the battery which helps to predict the discharge capacity by using a CD-Net. The data collected by the BMS uses a wired transfer method due to its high-speed communication between the BMS and computer for the prediction of capacity. Coulomb counting uses the initial capacity (Qₙ) provided in the data sheet of the battery pack (also mentioned in Table 3) along with the continuous current following into the battery pack to calculate the SOC. The SOC of each cycle along with the nominal capacity and cell chemistry are fed into the CD-Net model developed by the authors of the present disclosure for predicting the upcoming cycle maximum capacity. A combination of autoencoder with perceptron was used in the CD-Net model. 4 historical cycles of data were fed into the CD-Net, and using autoencoder the noise in the data was removed to highlight the temporal vectors responsible for degradation of the battery. A rectified linear activation function with mean squared error as a loss function was used in the CD-Net model for better predictions. The maximum capacity of the upcoming cycle predicted by the CD-Net model is used to calculate the SOH, a ratio of the predicted maximum capacity to the nominal battery capacity.

Tests were conducted on an 18650 Sony VTC 6 battery pack with 4 cells in series. The specifications of the individual cell are listed in Table 3. The lithium nickel cobalt aluminum oxide (NCA) cells were selected which have a higher risk of thermal runaway when compared to other cell chemistries such as lithium cobalt oxide (LCO) or lithium iron phosphate (LFP). The battery pack has a capacity of 3 Ah with a maximum voltage of 16.8 V. Each cell weighs approximately 46.4 g, and the entire battery pack weighs approximately 186 g. Each cell is said to be fully charged when the voltage reaches 4.2 V, and fully discharged when they reach 2.5 V, according to datasheet standard cycle is defined as when the battery was charged under constant current constant voltage (CCCV) at 3 A of current and discharged under constant current discharge at 3 A of current.

TABLE 3
Specifications of the individual cells in
the LiB battery pack used in this study

| Characteristic | Value | |
|---|---|---|
| Cell Chemistry | NCA | |
| Cell form factor | 18650 | |
| Nominal Capacity | 3120 | mAh |
| Nominal Voltage | 3.6 | V |

| | |
|---|---|
| Standard Charge | CCCV, 1 C, 4.2 V |
| Standard Discharge | Constant Charge, 1 C, 2.5 V |
| Weight | 46.4 g +/− 1.5 g |

On-ground tests were done to analyze the performance of newly developed BMS before deploying them in electric propulsion vehicles. On-ground tests involved applying load to the battery which can charge and discharge by connecting BMS in between the battery pack and the battery analyzer (BAn) as shown in FIG. 6b. FIGS. 6a, 6b, 6c, and 6d are schematic overview of an experimental setup: where FIG. 6a provides a top view of BMS with all the sensors used in these experiments, FIG. 6b is a schematic representation of BMS and quadcopter connectivity with batteries, FIG. 6c is a schematic showing in operation experimental setup of quadcopter along with batteries and BMS, and FIG. 6d is a schematic of an 18650 NCA batteries used in batteries where RTD is placed in the middle of the surface. NEWARE Powerwall CT-4004-20V20 A system BAn, capable of charge and discharge of up to a combined 20 V and 20 A was considered as a load during on-ground testing. The voltage, current of the battery pack, and surface temperature of each cell were monitored, and BMS logged data. For placing the RTD on the battery, the protective film of the battery was removed at the center of the 18650 and the orientation of the battery pack was noted to maintain consistency in recording the surface temperature as shown in FIG. 6d. In addition, voltage and applied current on the battery pack were collected by BAn. Following the standard cycle on the battery pack, an additional 10 cycles were performed to check the performance of the newly developed BMS. The cycling pattern was similar to NASA's certification experiment bed for small satellites.

After performing the on-ground experiments, real-time data in-air testing was performed for 10 charge-discharge cycles. This testing was performed to gather data under high discharge rates. Real-time data was collected using an electric propulsion vehicle or quadcopter that is FLYWOO Explorer, with 2750 KV motors that can spin 2750 RPM per volt including a GOKU GN405 Nano flight controller with Atomic 5.8 GHz antenna for point-to-point communication. Without the battery, the quadcopter weighs 162.8 g. The quadcopter was chosen for its real-world usage and ability to draw high currents from the battery pack. The battery pack was installed in a 3D-printed mounting frame to support the BMS on top as seen in FIG. 6c. With the BMS weighing 113 g. The battery charging protocol remained consistent with the on-ground procedure, utilizing the datasheet of the battery pack. After each charging cycle, approximately 10 minutes were required to prepare for in-air discharge. Unlike the controlled discharge patterns employed during ground testing, the in-air discharge cycles were randomized to simulate real-world variations. The quadcopter flew approximately 1 foot above ground level during discharge. When the BMS indicated that the battery voltage had reached 10 V, the in-air discharge was stopped. Following a 10-minute rest period, the charging cycle was performed.

Using the previous experimental setup for on-ground and in-air experiments, the newly developed BMS collects data in both stationary battery loads and dynamic. Newly developed BMS also seamlessly integrates deep learning models like CD-Net of the present disclosure providing more flexibility to adapt to evolving technological needs.

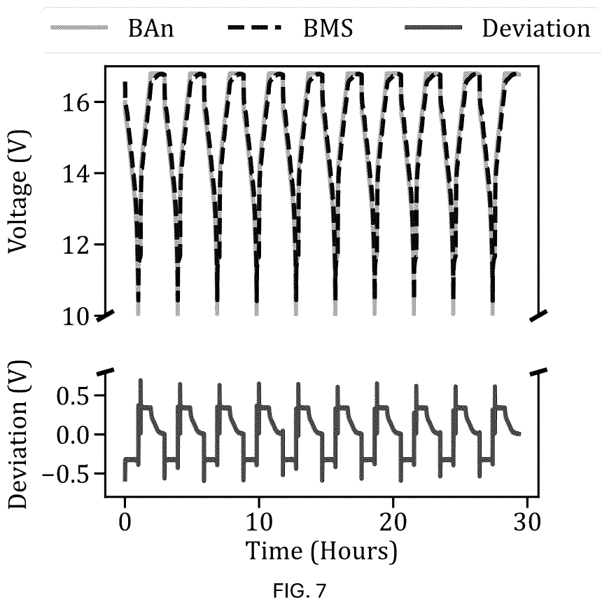

FIG. 7 is a graph of voltage in volts and deviation of voltage in volts vs. time in hours, showing comparison of voltage readings collected from both BMS and BAn on top with the deviation between them plotted on the bottom indicating the error between BMS and BAn readings is minimal. FIG. 7 illustrates voltage versus time data for 10 cycles of charging and discharging from BAn and a newly developed BMS. Each cycle comprises approximately 1.62±0.2 hours of charging followed by 1±0.2 hours of discharging. During the charging phase, there was a rapid voltage increase in the initial part, then a slower rise as observed previously and followed by constant voltage charging. The constant voltage charging lasts for more than 0.5±0.1 hours. The voltage data acquired by the BMS closely matches that of the BAn, although a slight initial lag was observed in the BMS data, which subsequently converged with the BAn readings. The constant voltage portion of the discharge curve can be further investigated to establish a direct correlation with the battery's SOH. It can be observed from FIG. 7 that the discharge cycles primarily feature constant current, leading to rapid voltage reduction until reaching 10 V similar, variations were observed only due to the time-sensitivity of BMS. Discrepancies in the lowest values arise from BMS's 5-second data transfer rate and a delay in the internal clock for both systems. Notably, BMS relies on battery power, causing an initial voltage to drop absent in BAn, powered externally. The observed average deviation of 0.097 V between BMS and BAn, along with the logarithmic curve during constant current, indicates a close match. In previous works, it was observed an accuracy error of just above 0.05±0.01 V while performed on-ground with hardware in the loop (HIL) simulator. Overall, the results suggest good alignment, with minor variations attributed to the power source and internal clock discrepancies between BMS and Ban.

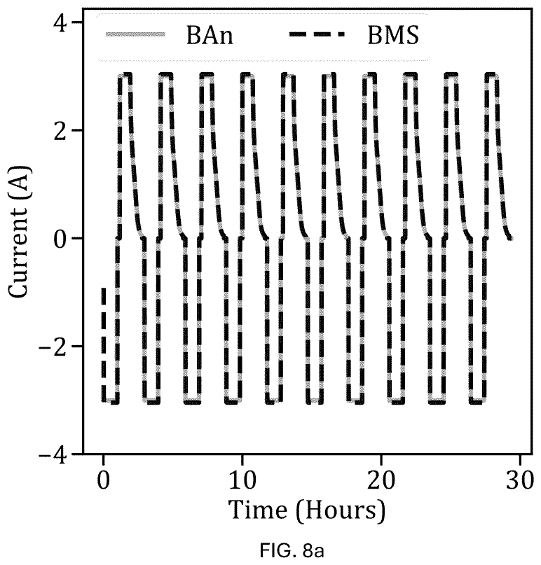

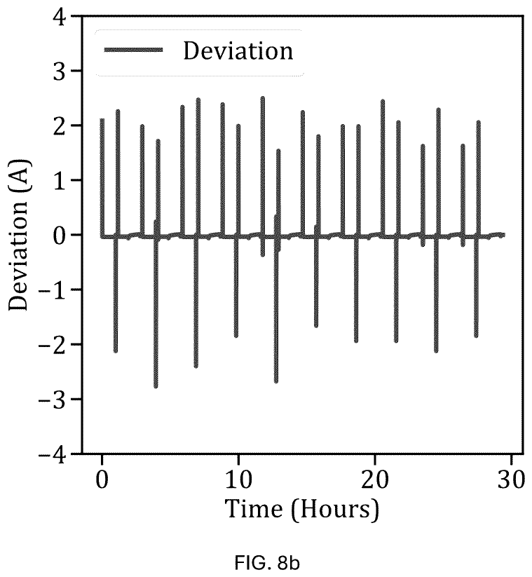

FIG. 8a is a graph of current in amperes vs. time in hours showing current collected from both BMS and BAn. FIG. 8b is a graph of deviation in current in amperes vs. time in hours showing good match for current collected from both BMS and BAn except during the transition from charge to discharge or discharge to charge for on-ground experiments. FIGS. 8a and 8b illustrate the current flowing by the BAn during 10 cycles on-ground. The negative values in the figure represent the current drawn from the battery during discharge. BAn draws current up to −3 A during the constant current phase of discharge. BMS data showed a good match with the BAn data. After discharging at −3 A for 1±0.2 hour, the current draw was 0 A for the 10 minutes of rest. The current shoots up to +3 A to charge the battery at a constant current charge as in previous work. The constant current phase at charging would take around 0.8±0.2 hours. Constant voltage charge would begin after the constant current charge. The negative slope after each constant current charge phase represents the constant voltage charge of the battery. During this constant voltage charge current supplied to the battery gradually increased to reach 16.8 V in the battery. Data collected from BMS showed close agreement. Except for the part where the current shoots up before each constant current phase BMS was delayed in reading these values because it reads the current flowing to the battery causing deviation higher than 0.25 A in certain instances. The highest voltage deviations were observed when the battery's charging phase shifted from constant current to constant voltage. Current readings were more accurate than the voltage readings of the BMS with the lesser average deviation of 0.044 A. But when the data points for deviation over 0.25 A were removed the average deviation was 0.005 A. This was due to the lower shunt resistance used to measure voltage drop relating to current by Ohm's law.

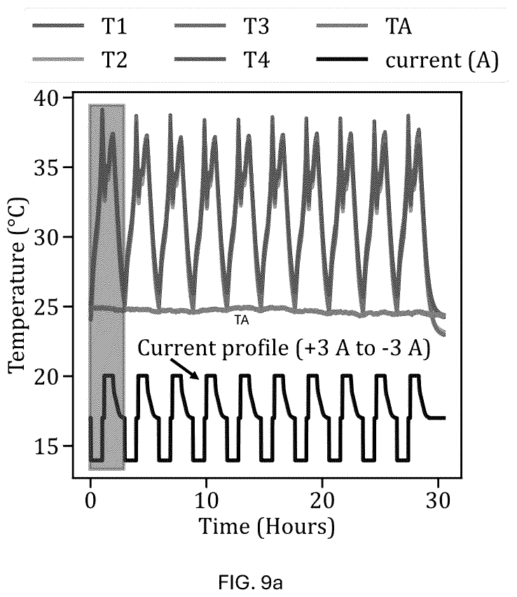

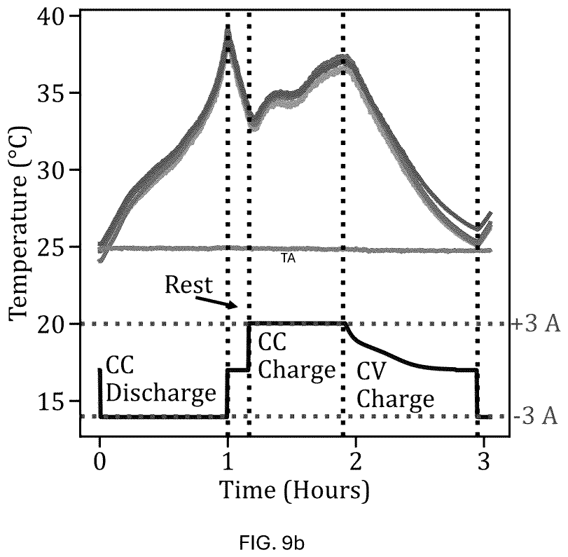

Four surface temperatures were collected to monitor the rise of temperature of each cell for all 10 cycles. A rapid surface temperature rise was observed during the cycling of the battery for each cell. Similar observations were made previously. In FIG. 9a, which is a graph of temperature in ° C. vs. time in hours showing surface temperature for a 4-cell battery pack including the ambient temperature (T5=TA) data logged by BMS for 10 cycles performed on ground, in the first cycle, each cell was at room temperature 24° C.±0.3 (TA) before the beginning of on-ground experiments. After on-ground experiments were begun, there was a gradual rise in temperature due to the constant current drawn from the battery pack during discharge. Rising from room temperature the surface temperature reached just above 38±0.3° C. for each cell in the battery pack at the end of constant current discharge. Then a decrease in the surface temperature was observed due to the 10 mins rest time. Then constant current charge was applied by BAn on the battery causing the temperature to rise to 37.6° C. Constant voltage charge for the battery made the surface temperature decrease gradually similar observations were made previously. After that 10 minutes of rest was provided, and at this time the surface temperature of the battery reached room temperature. The highest temperatures were observed at the end of each constant current phase of the battery. These observations were consistent with all the cycles performed on the ground as shown in FIG. 9a. Overall, the surface temperature of all four cells in the battery pack with ambient temperature was recorded.

The surface temperature for cell 1 was observed to be comparatively higher than the other 3 cells in the battery pack as shown in FIG. 9a. Due to many reasons such as aging of the battery, SOC change of battery, and many more. The thermal performance of each cell has an overall impact on the battery pack behavior and power capabilities of each cell, BMS shows the temperature difference observed in each cell. Recognizing this early can be useful in replacing the cell or finding suitable thermal management techniques.

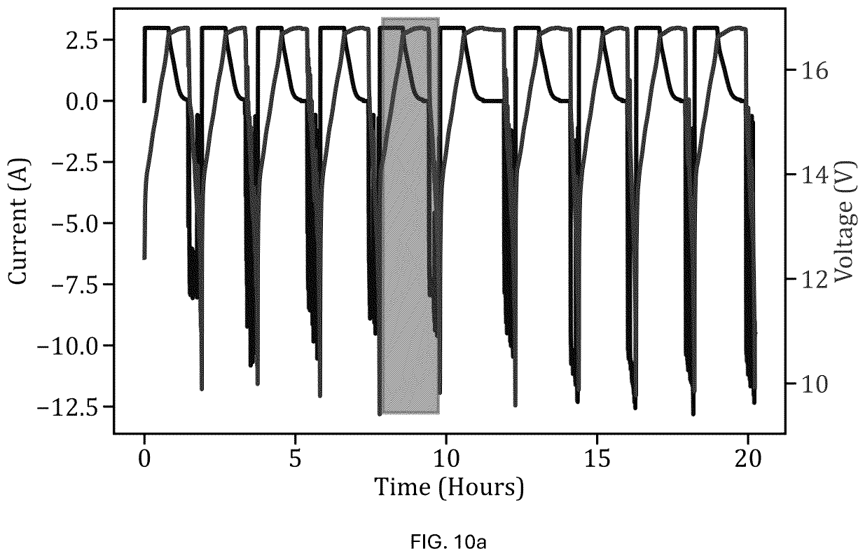

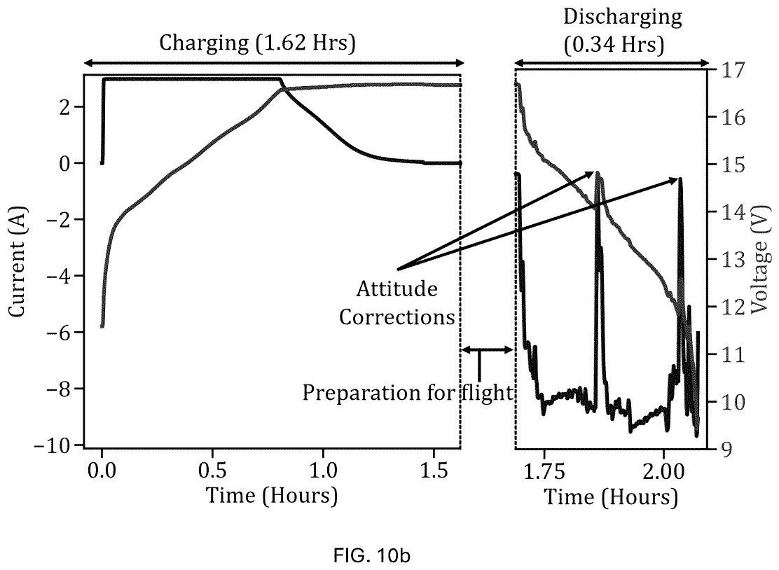

FIG. 10a, which is a graph of current in ampere vs. time in hours for current and voltage collected by BMS performing random flying pattern of the drone, current and voltage were collected over 10 cycles performed on drone with required discharge current from the battery pack to fly the drone, illustrates the current and voltage readings collected by the newly developed BMS in-air. For each cycle in-air the current drawn by the quadcopter was random according to the power needs of the quadcopter as shown in FIG. 10a. As shown in FIG. 10b, which is another graph of current in ampere vs. time in hours similar to FIG. 10a, but where current discharging at higher ° C. rates in real-time while voltage dropping from 16.8V to 10V for one discharge cycle while flying the graph was for 5^{th} cycle out of 10, note that discharge cycle is less than an hour, the charging of LIB was performed on-ground which was similar to FIG. 7. FIG. 10b represents the 5^{th} cycle performed in-air testing. At the end of the charge, 10±2 minutes of preparation for the flight was the time required to integrate the BMS and quadcopter and prepare the station for flying as shown in FIG. 6c. At the beginning of the flight, the current drawn from the battery sharply increases until reaching the required power for an electric-propelled quadcopter in this case it was approximately 8 A. After reaching the required power, the current drawn was consistent with little fluctuations in flight to maintain the attitude and altitude of the flight. At around 10 minutes the current drawn rapidly goes to zero, due to the cut-off power to correct the attitude of flight. Then restarting the experiment observed an increase in current drawn and it was 9 A. The spikes in the current profile before the end of the experiment were due to the attitude corrections made. The rise in voltage observed at the attitude correction points was considered an outlier of the data. The current drawn by the drone to maintain the attitude and altitude increased over the 10 cycles conducted in-air as shown in FIG. 10a. The discharge current began at a maximum of 10 A for the first experiment. Then it showed an increase reaching the highest discharge current of 13 A at the 9^{th} cycle in-air. For the last 4 cycles in-air, the current drawn from the battery was never less than 12 A. The current drawn from the batteries was at higher C rates than the on-ground experiments and BMS was capable of recording the currents at high C rates.

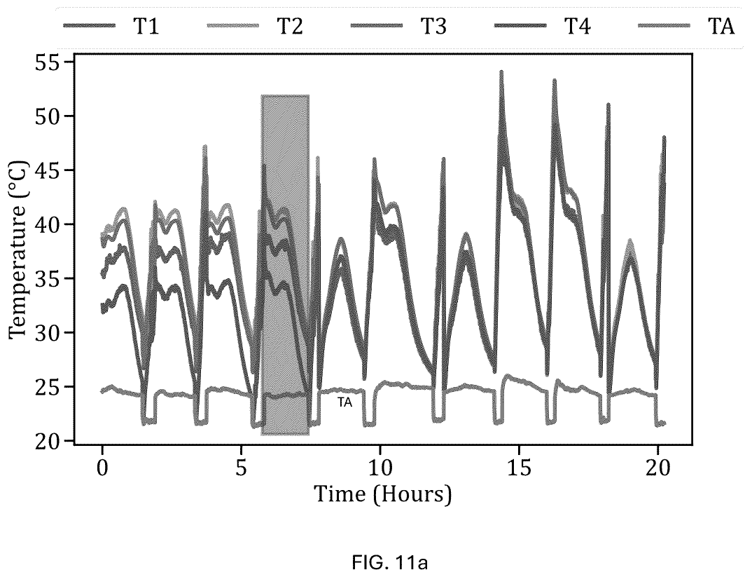

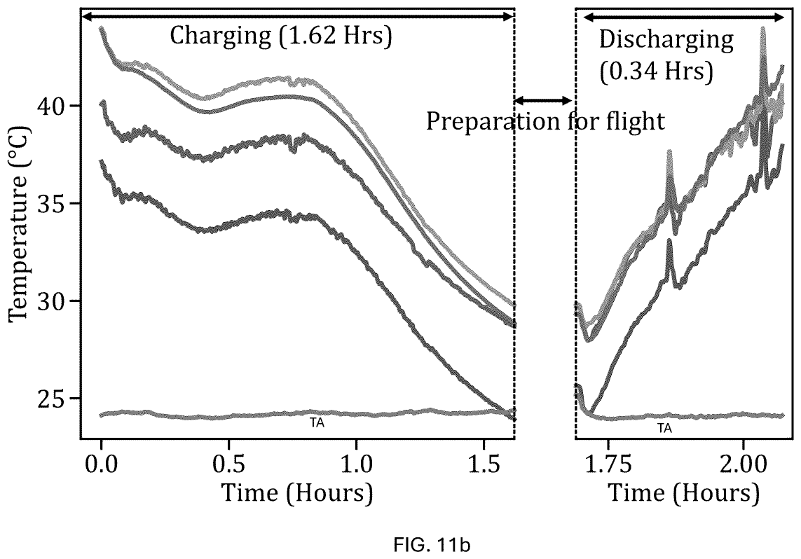

FIG. 11a, which is a graph of temperature in ° C. vs. time in hours showing surface temperature collected by BMS performing random flying pattern on drone including TA as ambient temperature using a 4 cell LIB pack where similar pattern was observed for the 10 cycles performed on drone with TA dipping during the flight, shows each cell surface temperature of the battery pack collected during the in-air experiments. FIG. 11b, which is similar to FIG. 11a but providing data for one discharge cycle while flying in which a temperature growth was observed over time, note that discharge cycle is less than an hour, indicates the temperature of each cell for the 5^{th} cycle performed in-air, as cell temperature starts below 45° C. observed reduction in surface temperature while charging of LIB. While discharging in-air (FIG. 11b) the ambient temperature indicates a dip due to the air flowing around the cells. The surface temperature increases gradually during the discharge reaching the highest value of around 45±0.3° C. The maximum temperature reached on-ground was around 39° C., indicating a 6.5±0.3° C. rise in surface temperature for the cells. The increase in surface temperature of the battery is due to the high C discharge rate performed in-air. The sudden hicks observed in temperature at 10 mins and after 20 mins were due to the attitude correction made. T4 in FIGS. 8a and 8b showed the offset values compared to other cells in the battery pack. It may be due to the cell imbalance of the battery. As illustrated in FIG. 11a, the first 5 cycles of T2 showed a higher temperature than other cells in the pack. After the 5^{th} cycle, T3 showed an increase in temperature than T2. Peaks of temperature were observed first at the 7^{th} cycle of in-air because the current at that cycle crossed 4 C discharge for the first time within 10 cycles. Notably, it reached the highest temperature around 55 C which was 16±0.5 C higher than the peak temperature observed on the ground. Also 10±0.5° C. higher than the 1^{st} cycle in-air experiment. Overall, the temperature observed in-air experiment was higher than in the on-ground experiment.

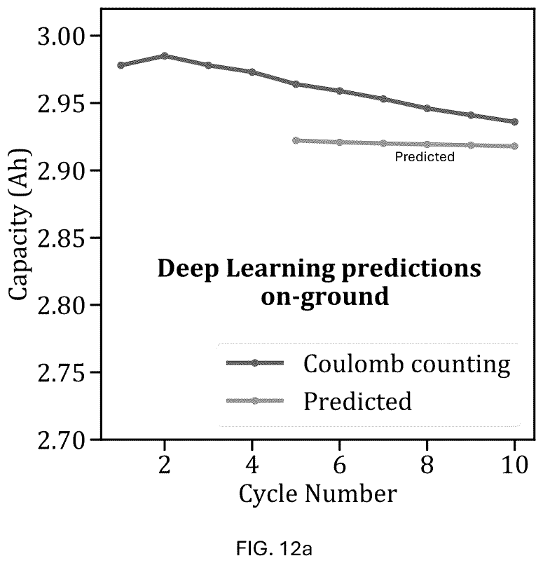

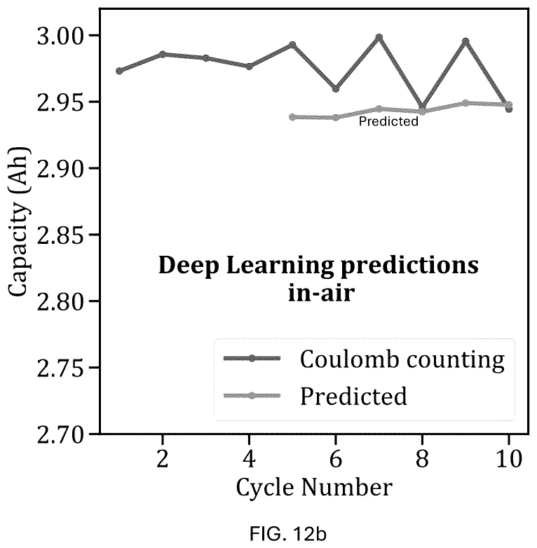

Data collected from BAn and BMS were used to calculate the discharge capacity of the battery over each cycle. Less capacity loss was observed over the 10 cycles on-ground as seen in FIG. 12a. FIGS. 12a and 12b are graphs of capacity in Ah vs. cycle number showing capacity predictions made on the CD-Net model based on the data collected from BMS for both on-ground experiments (FIG. 12a) and while flying on a drone with capacity being unstable after 4 cycles (FIG. 12b). FIG. 12a illustrates the peak capacity noted in each cycle experimented on-ground. The blue line represents the capacity calculated using coulomb counting on-ground. At the initial cycle battery capacity observed a rise due to instability in the initial cycles of the battery. From the second cycle, the battery capacity followed a gradual decrease over the cycles. At the end of the 10^{th} cycle, the capacity of the battery was 2.94 Ah. Capacity predictions started from the 5^{th} cycle, at 2.92 Ah, whereas the 5^{th} cycle coulomb counting capacity was 2.96 Ah as recorded by BMS. Capacity had a gradual drop over cycles predictions from the model was consistent with BMS capacity with a difference of around 0.018±0.003 Ah at the 10^{th} cycle. This can be further used to predict the approximate SOH of the battery for that cycle. As observed in FIG. 12b, discharge capacity predictions of the battery during flying tests were more unstable than the on-ground tests. The mean difference between the calculated coulomb counting capacity and the predicted capacity observed in air was 0.028 Ah. Despite fluctuations observed in collecting the in-air data CD-Net model was able to predict the upcoming cycle capacity. Predicting upcoming cycle capacity helps the development of BMS by calculating the RUL of the battery pack.

In operation, data collection needs a portable BMS which can operate in an abuse condition like a high C rate discharge on LIB. In this study, BMS architecture was proposed to transmit and receive data using edge and cloud frameworks that can perform high C rate discharge. Using the data collected, the deep learning model CD-Net helps in predicting the RUL of the battery. This BMS architecture enhances traditional systems by substituting the conventional approach that relies on a CAN bus and an edge computer. Two types of tests have been performed such as the on-ground test and in-air or in-operando test. The highest surface temperature both on-ground and in-air was observed at the end of the constant current phase of discharge. In-air tests showed an increased surface temperature of the battery including a differential temperature between each cell in the battery pack, maximum surface temperature by a battery was close to 55° C. This can be due to aging, SOC change, and many more; the reason for this is beyond the scope of this paper. But this high increase in surface temperature eventually leads to the failure of that cell or even the whole battery pack. Throughout the 10 cycles performed both on-ground and in-air, the in-air surface temperature increased over the cycles performed. The deep learning model predicted the upcoming cycle capacity was consistent even with the fluctuations during the data collected in-air with a mean difference of 0.28 Ah from the calculated coulomb counting capacity. Within the threshold limit of the current-voltage sensor (±32 A), BMS can be able to perform the data collection.

Those having ordinary skill in the art will recognize that numerous modifications can be made to the specific implementations described above. The implementations should not be limited to the particular limitations described. Other implementations may be possible.

1. A method of predicting battery end of life based on a small dataset of sensor data,
comprising:
training a deep learning network using a plurality of apriori generated training datasets;
receiving sensor data from a plurality of sensors in real-time coupled to one or more cells in a battery pack as the one or more cells are used in a present discharge cycle to thereby generate a plurality of new unseen sensor datapoints; and
applying the new unseen sensor datapoints to the trained deep learning network to thereby generate operational recommendations to achieve one or both of i) extend end of life of the battery pack, and ii) extend operational time of the battery pack during the present discharge cycle or a future discharge cycle.

2. The method of claim 1, wherein the deep learning network is a neural network.

3. The method of claim 1, wherein the plurality of sensor data include voltage data from one or more voltage sensors from one or more cells in the battery pack.

4. The method of claim 1, wherein the plurality of sensor data include current data from one or more current sensors from one or more cells in the battery pack thus generating current vs. time datapoints.

5. The method of claim 1, wherein the plurality of sensor data include temperature data from one or more temperature sensors from one or more cells in the battery pack.

6. The method of claim 1, wherein the plurality of sensor data include ambient temperature data from one or more ambient temperature sensors.

7. The method of claim 1, wherein the trained deep learning network considers capacity vs. cycle from a plurality of battery designs.

8. The method of claim 7, wherein the plurality of training sensor datapoints include a flag representing an associated battery design to enable the deep learning network to correspond the plurality of training sensor datapoints with the associated battery design.

9. The method of claim 7, wherein the deep learning network is blind to an associated battery design when receiving the new unseen sensor datapoints.

10. The method of claim 7, wherein the deep learning network receives a flag corresponding to the associated battery design when receiving the new unseen sensor datapoints to thereby associate the new unseen sensor datapoints with an associated battery design.

11. A system for predicting battery end of life based on a small dataset of sensor data,
comprising:
a plurality of sensors coupled to one or more cells in a battery pack and adapted to provide real-time sensor data;
a battery management system configured to operate the one or more cells;
a processing system including a processor executing instruction residing on a non-transitory memory, the processor configured to receive the real-time sensor data;
the processor configured to communicate with a deep learning network, wherein the deep learning network is trained based on a plurality of a priori generated training datasets,
where the processor is configured to:
receive the real-time sensor data as the one or more cells are used in a present discharge cycle to thereby generate a plurality of new unseen sensor datapoints; and
apply the new unseen sensor datapoints to the trained deep learning network to thereby generate operational recommendations to achieve one or both of i) extend end of life of the battery pack, and ii) extend operational time of the battery pack during the present discharge cycle or a future discharge cycle.

12. The system of claim 11, wherein the deep learning network is a neural network.

13. The system of claim 11, wherein the plurality of sensor data include voltage data from one or more voltage sensors from one or more cells in the battery pack.

14. The system of claim 11, wherein the plurality of sensor data include current data from one or more current sensors from one or more cells in the battery pack thus generating current vs. time datapoints.

15. The system of claim 11, wherein the plurality of sensor data include temperature data from one or more temperature sensors from one or more cells in the battery pack.

16. The system of claim 11, wherein the plurality of sensor data include ambient temperature data from one or more ambient temperature sensors.

17. The system of claim 11, wherein the trained deep learning network considers capacity vs. cycle from a plurality of battery designs.

18. The system of claim 17, wherein the plurality of training sensor datapoints include a flag representing an associated battery design to enable the deep learning network to correspond the plurality of training sensor datapoints with the associated battery design.

19. The system of claim 17, wherein the deep learning network is blind to an associated battery design when receiving the new unseen sensor datapoints.

20. The system of claim 17, wherein the deep learning network receives a flag corresponding to the associated battery design when receiving the new unseen sensor datapoints to thereby associate the new unseen sensor datapoints with an associated battery design.
